(19) United States
(12) Patent Application Publication
(10) Pub. No.: US 2014/0284095 A1
(43) Pub. Date: Sep. 25, 2014

(54) DEVICE FOR ELIMINATING CELL PHONE TRACKING

(71) Applicants: Scott Behuniak, Tampa, FL (US); Michael Kovac, Temple Terrace, FL (US)

(72) Inventors: Scott Behuniak, Tampa, FL (US); Michael Kovac, Temple Terrace, FL (US)

(21) Appl. No.: 14/163,551

(22) Filed: Jan. 24, 2014

Related U.S. Application Data
(60) Provisional application No. 61/756,837, filed on Jan. 25, 2013.

(51) Int. Cl. H05K 9/00

(52) U.S. Cl. CPC H05K 9/0007
USPC 174/377

(57) ABSTRACT

A shielding system includes a resealable enclosure configured to receive a handheld device. An electroconductive layer is configured to magnetically and/or electrically shield the handheld device.

### RELATED APPLICATION

This application claims the benefit of U.S. Provisional Patent Application No. 61/756,837, filed on 25 Jan. 2013, and entitled “Device for Eliminating Cell Phone Tracking”, the entire disclosure of which is incorporated herein by reference.

### TECHNICAL FIELD

This disclosure relates to shielding systems and, more particularly, to shielding systems that are configured to work with handheld communication devices.

### BACKGROUND

The technology of locating is based on measuring power levels and antenna patterns and uses the concept that a mobile phone always communicates wirelessly with one of the closest base stations, so if you know which base station the phone communicates with, you know that the phone is close to the respective base station.

Advanced systems determine the sector in which the mobile phone resides and roughly estimate also the distance to the base station. Further approximation may be done by interpolating signals between adjacent antenna towers. Qualified services may achieve a precision of down to 50 meters in urban areas where mobile traffic and density of antenna towers (base stations) is sufficiently high. Rural and desolate areas may see miles between base stations and therefore determine locations less precisely. GSM localization is the use of multilateration to determine the location of GSM mobile phones, usually with the intent to locate the user.

Network-based techniques utilize the service provider's network infrastructure to identify the location of the handset. The advantage of network-based techniques (from mobile operator's point of view) is that they may be implemented non-intrusively, without affecting the handsets.

The accuracy of network-based techniques varies, with cell identification as the least accurate and triangulation as moderately accurate, and newer “Forward Link” timing methods as the most accurate. The accuracy of network-based techniques is both dependent upon the concentration of base station cells, with urban environments achieving the highest possible accuracy and the implementation of the most current timing methodologies.

Handset-based technology requires the installation of client software on the handset to determine the location of the handset. This technique may determine the location of the handset by computing its location by cell identification, signal strengths of the home and neighboring cells, which is continuously sent to the carrier. In addition, if the handset is also equipped with GPS then significantly more precise location information is then sent from the handset to the carrier.

Additionally, using the SIM in GSM and UMTS handsets, it is possible to obtain raw radio measurements from the handset. The measurements that are available may include the serving Cell-ID, round trip time and signal strength. The type of information obtained via the SIM can differ from what is available from the handset. For example, it may not be possible to obtain any raw measurements from the handset directly, yet still obtain measurements via the SIM.

Hybrid positioning systems may use a combination of network-based and handset-based technologies for location determination. One example would be some modes of Assisted GPS, which can use both GPS and network information to compute the location. Both types of data are thus used by the handheld device to make the location more accurate (e.g., A-GPS). Alternatively tracking with both systems may also occur by having the handheld device obtain its GPS-location directly from the satellites, and then have the information sent via the network to the person that is trying to locate the telephone.

In order to route calls to a phone, the cell towers may listen for a signal sent from the phone and negotiate which tower is best able to communicate with the phone. As the phone changes location, the antenna towers monitor the signal and the phone is roamed to an adjacent tower as appropriate.

By comparing the relative signal strength from multiple antenna towers, a general location of a phone may be roughly determined. Other means is the antenna pattern that supports angular determination and phase discrimination. Newer phones may also allow the tracking of the phone even when turned on and not active in a telephone call-. This results from the roaming procedures that perform handover of the phone from one base station to another base station.

Of course, the locating or positioning of these handheld devices touches upon delicate privacy issues, since it enables someone to check where a person is without that person's consent. Strict ethics and security measures are strongly recommended for services that employ positioning, and the user may need to give an informed, explicit consent to a service provider before the service provider may compute positioning data from the user's handheld device.

Officially, the authorities can obtain permission to position/locate handheld devices in emergency cases where people (including criminals) need to be located. The U.S. Justice Department has argued that current laws allow the authorities to track suspects without having probable cause to suspect a law is being violated. In some instances law enforcement may even access a handheld device's internal microphone to eavesdrop on local conversations while the phone is switched off.

### SUMMARY OF DISCLOSURE

In one implementation, a shielding system includes a resealable enclosure configured to receive a handheld device. An electroconductive layer is configured to magnetically and/or electrically shield the handheld device.

One or more of the following features may be included. The electroconductive layer may be configured to shield the handheld device from radio-frequency waves. The shielding system may be configured to function as a Faraday cage. The electroconductive layer may be applied to the resealable enclosure. The electroconductive layer may be constructed, at least in part, from a metallic material. The handheld device may be a cellular telephone. The resealable enclosure may include: a compartment enclosure portion, and a lid enclosure portion. The electroconductive layer may include an electroconductive compartment layer configured to shield the compartment enclosure portion. The electroconductive layer may include an electroconductive lid layer configured to shield the lid enclosure portion. The resealable enclosure may be configured to function as a case for the handheld device. The resealable enclosure may be constructed of a rigid material. The resealable enclosure may be constructed of a non-rigid material.

In another implementation, a shielding system includes a resealable enclosure configured to receive the cellular telephone. An electroconductive layer is configured to magnetically and/or electrically shield the cellular telephone, wherein the electroconductive layer is applied to the resealable enclosure.

One or more of the following features may be included. The electroconductive layer may be configured to shield the handheld device from radio-frequency waves. The electroconductive layer may be constructed, at least in part, from a metallic material. The resealable enclosure may include a compartment enclosure portion and a lid enclosure portion. The electroconductive layer may include an electroconductive compartment layer configured to shield the compartment enclosure portion and an electroconductive lid layer configured to shield the lid enclosure portion.

In another implementation, a shielding system includes a resealable enclosure configured to receive a cellular telephone. The resealable enclosure includes a compartment enclosure portion and a lid enclosure portion. An electroconductive layer is configured to magnetically and/or electrically shield the cellular telephone. The electroconductive layer includes an electroconductive compartment layer configured to shield the compartment enclosure portion and an electroconductive lid layer configured to shield the lid enclosure portion.

One or more of the following features may be included. The shielding system may be configured to function as a Faraday cage. The electroconductive layer may be applied to the resealable enclosure. The resealable enclosure may be configured to function as a case for the handheld device.

The details of one or more implementations are set forth in the accompanying drawings and the description below. Other features and advantages will become apparent from the description, the drawings, and the claims.

### BRIEF DESCRIPTION OF THE DRAWINGS

FIGS. 1A-1B are diagrammatic views of two embodiments of a shielding system for a handheld device according to an implementation of the present disclosure;

FIG. 2 is a diagrammatic view of another embodiment of the shielding system of FIGS. 1A-1B according to an implementation of the present disclosure;

FIG. 3 is a diagrammatic view of another embodiment of the shielding system of FIGS. 1A-1B according to an implementation of the present disclosure;

FIG. 4 is a diagrammatic view of another embodiment of the shielding system of FIGS. 1A-1B according to an implementation of the present disclosure; and

FIG. 5 is a diagrammatic view of another embodiment of the shielding system of FIGS. 1A-1B according to an implementation of the present disclosure.

Like reference symbols in the various drawings indicate like elements.

### DETAILED DESCRIPTION

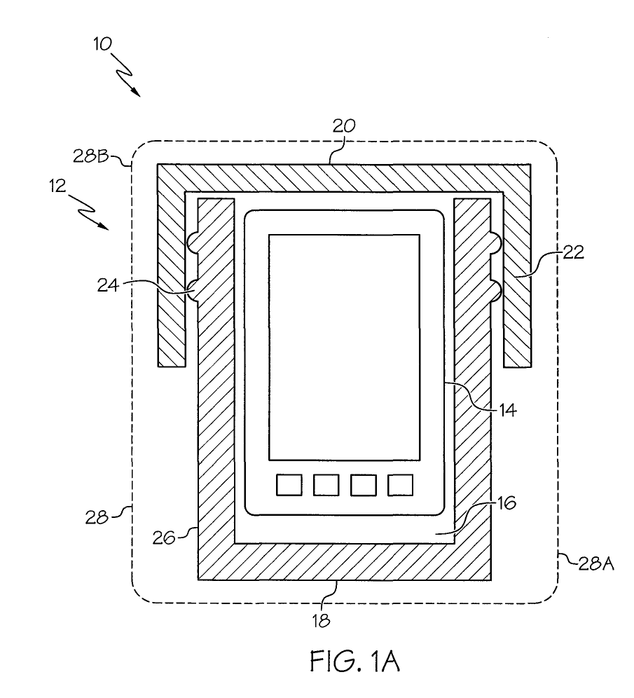

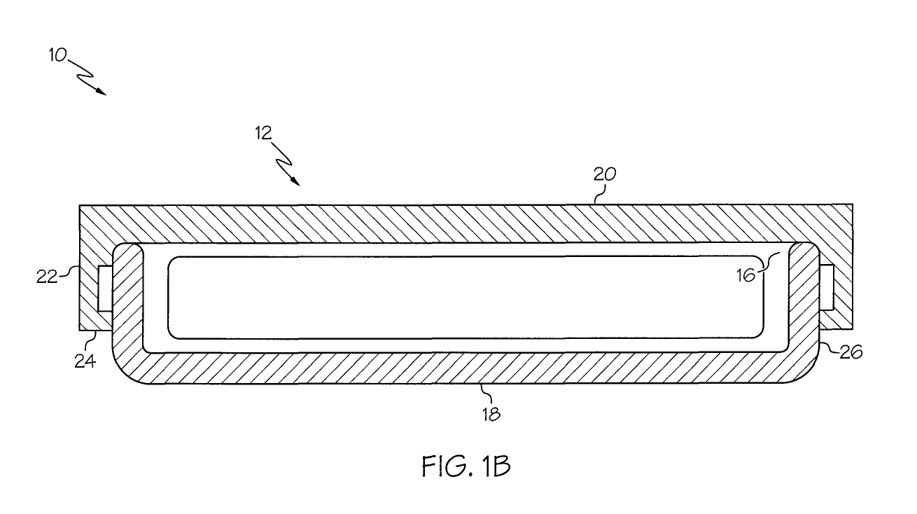

Referring to FIGS. 1A-1B, there is shown shielding system 10, which may include resealable enclosure 12 configured to receive handheld device 14. Resealable enclosure 12 may define interior volume 16 into which handheld device 14 may be placed. Examples of handheld device 14 may include but are not limited to a cellular telephone, a smart phone, a personal digital assistant, and a tablet computer. One or more portions of resealable enclosure 12 may be constructed of a variety of materials, examples of which may include but are not limited to: ABS plastic, polycarbonate plastic, aluminum, and titanium.

Resealable enclosure 12 may include compartment enclosure portion 18 and lid enclosure portion 20, wherein lid enclosure portion 20 may be configured to releasable engage compartment enclosure portion 18. Lid enclosure portion 20 may include one or more arms (e.g., arm 22) adapted to engage one or more protrusions (e.g., protrusion 24) positioned on e.g., a surface (e.g., surface 26) of compartment enclosure portion 18. Accordingly and through the use of e.g., arm 22 and protrusion 24, a seal may be formed between compartment enclosure portion 18 and lid enclosure portion 20. Depending on the manner in which compartment enclosure portion 18 and lid enclosure portion 20 are configured, this seal may be waterproof. Compartment enclosure portion 18 and lid enclosure portion 20 may be constructed (at least in part) of a conductive material. An example of such a conductive material may include a metallic material (e.g., aluminum). Alternatively, a conductive material may be applied to enclosure portion 18 and lid enclosure portion 20.

Accordingly and in such a configuration, due to one or more arms (e.g., arm 22) being in contact with one or more protrusions (e.g., protrusion 24), the combination of enclosure portion 18 and lid enclosure portion 20 may form an electroconductive layer (e.g., electroconductive layer 28) that may be configured to magnetically and/or electrically shield handheld device 14.

Accordingly, electroconductive layer 28 may include electroconductive compartment layer 28A configured to shield compartment enclosure portion 18 and electroconductive lid layer 28B configured to shield lid enclosure portion 20.

For example, electroconductive layer 28 may be configured to shield handheld device 14 from radio-frequency waves that e.g., may be used to track the location of handheld device 14 using one of the tracking methodologies described above. Accordingly and through the use of electroconductive layer 28, shielding system 10 may be configured to function as a Faraday Cage with respect to handheld device 14. As is known in the art, a Faraday cage (or Faraday Shield) is an enclosure formed of conducting material or by a mesh of such material. Such an enclosure may block external static and non-static electric fields by channeling electricity through the mesh, thereby providing a constant voltage on all sides of the enclosure. Since the difference in voltage is the measure of electrical potential, no current may flow through the space within the Faraday cage.

In the configuration shown in FIG. 1A, even if handheld device 14 is “turned on,” all inbound calls may be instantly directed to a voice mail system (or another location), as the cell towers cannot locate handheld device 14 and the cell towers will “think” handheld device 14 is “turned off’ or out or range. Accordingly, the location of handheld device 14 may not be determinable by the above-described tracking methodologies.

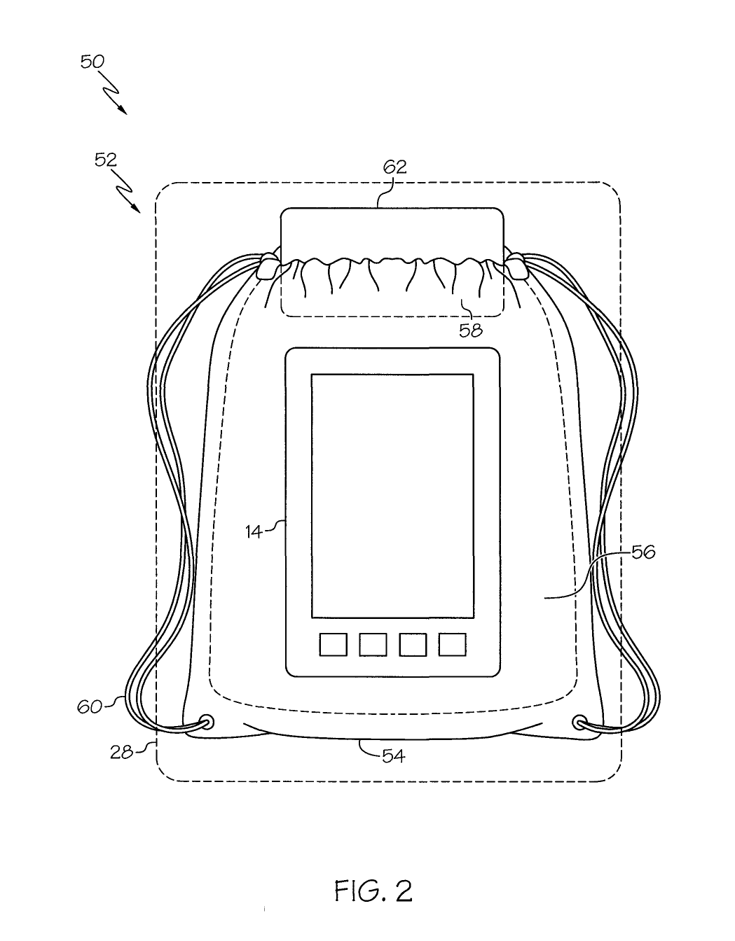

Referring also to FIG. 2, there is shown an alternative embodiment of shielding system 10 (i.e., shielding system 50), which includes resealable enclosure 52 in the form of a pouch/purse design that includes compartment enclosure portion 54 (defining interior volume 56 configured to receive handheld device 14) and opening 58 (through which handheld device 14 may be inserted). In an illustrative embodiment, compartment enclosure portion 54 may be constructed from a laminated material consisting of three flexible layers: an outer sheath (fabric or leather), a conductive middle layer (such as aluminum or Mylar with vacuum coated aluminum on both sides to form electroconductive layer 28) and an inner layer (fabric or leather). The fabric or leather may prevent wear and tear of electroconductive layer 28 while providing a variety of stylistic options. In this embodiment, shielding system 50 may be closed with a draw-string (e.g., drawstring 60) or similar closure device used for such a pouch/purse. Interior volume 56 may be sealed by providing an air-tight closure around opening 56 when drawstring 60 is closed. Alternatively, a conductive plug 62 (e.g., a flexible metal gauze or mesh that is easily compressible) may be placed in opening 58 to ensure the complete sealing and shielding of interior volume 56, thereby establishing the above-described Faraday Cage. Conductive plug 62 may be formed as an integral part of electroconductive layer 28 of the above-described lamination used for the body of shielding system 50.

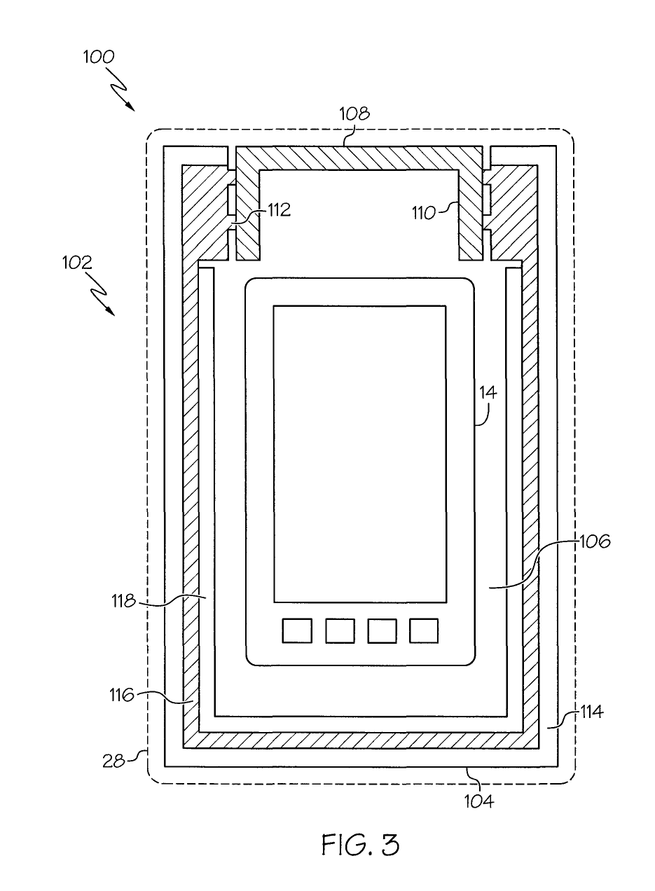

Referring also to FIG. 3, there is shown an alternative embodiment of shielding system 10 (i.e., shielding system 100), which includes resealable enclosure 102 in the general form of a conventional cell phone case (e.g., such as a cell phone case worn on a user's belt or carried in a user's pocket). This configuration may be semi-ridged and similar to the configurations shown in FIGS. 1A-1B, having compartment enclosure portion 104 (defining interior volume 106). Lid enclosure portion 108 may include one or more arms (e.g., arms 110) that may be configured to releasable engage one or more protrusions (e.g., protrusion 112). In this embodiment, compartment enclosure portion 104 may be a lamination of leather 114, metal foil 116 and leather 118. In this particular configuration, one or more protrusions (e.g., protrusion 112) may be constructed of metal foil 116 and may be configured to engage lid enclosure portion 108 (which may also be constructed of metal foil 116), thus establishing electroconductive layer 28 and shielding handheld device 14.

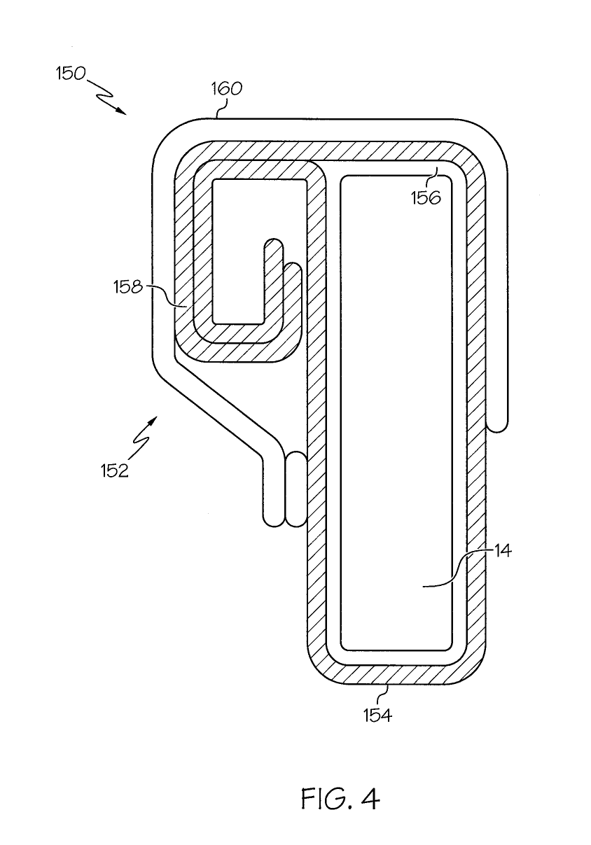

Referring also to FIG. 4, there is shown an alternative embodiment of shielding system 10 (i.e., shielding system 150), which includes resealable enclosure 152 in the general form of a pouch/purse. Shielding system 150 may include “non-rigid” compartment enclosure portion 154, which may be formed from an aluminum sheath and/or a laminated multilayered fabric. Interior volume 156 may be defined by the shape of compartment enclosure portion 154. Attached to the upper portion of compartment enclosure portion 154 is flexible extension 158 (which may also be constructed of a conductive material). To shield handheld device 14, the user may roll up flexible extension 158 into a coil and secure flexible extension 158 (in this coiled position) using flexible strap 160 that may be configured to include “hook and loop” fasteners. Alternatively, closure of compartment enclosure portion 154 may be accomplished via an alternative clamping mechanism (not shown).

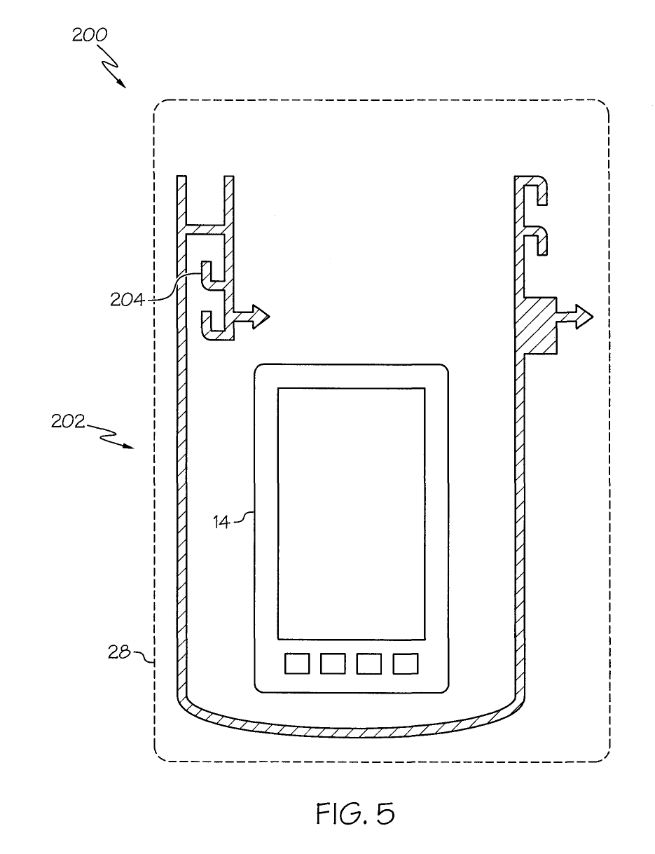

Referring also to FIG. 5, there is shown an alternative embodiment of shielding system 10 (i.e., shielding system 200), which includes resealable enclosure 202 that is configured to establish a “Faraday cage” via a sealing mechanism similar to a conventional zip lock plastic bag. As in known in the art, there are several types of zip lock closure mechanism known in the art. For example, a first type of closing device achieves a seal by aligning channels and having the user run their finger along the total length of the bag to achieve closure. A second kind of sealing mechanism utilizes a slider mechanism (not shown) to achieve closure.

Regardless of the type of zip lock sealing mechanism utilized, resealable enclosure 202 is configured to shield handheld device 14 via electroconductive layer 28. Accordingly, the interior of resealable enclosure 202 may be provided with an aluminized coating disposed continuously across the sealing channels (e.g., sealing channel 204). For example, sealing channel 204 may be made from a conductive material integrally attached/applied to resealable enclosure 202 (e.g., a flexible aluminized plastic or fabric bag) and configured so that when resealable enclosure 202 is sealed (using the above-described zip lock system), electroconductive layer 28 is established and handheld device 14 is shielded.

One or more of the above-described systems may be constructed in whole or in part from any combination of rigid material, semi-rigid material, or flexible material. Further, one or more of the above-described systems may be constructed in whole or in part from a transparent material (such as plastic or glass) to which an optically transparent electrically conductive coatings is applied. When configured in such a manner, handheld device 14 (generally) and a camera (not shown) included within handheld device 14 (specifically) may be used while positioned within the above-described shielding system 10, thus allowing a picture to be taken through the transparent material (while prohibiting the ability to have handheld device 14 tracked.

Having described the disclosure of the present application in detail and by reference to embodiments thereof, it will be apparent that modifications and variations are possible without departing from the scope of the disclosure defined in the appended claims.

What is claimed is:

1. A shielding system comprising:
a resealable enclosure configured to receive a handheld device; and
an electroconductive layer configured to magnetically and/or electrically shield the handheld device.

2. The shielding system of claim 1 wherein the electroconductive layer is configured to shield the handheld device from radio-frequency waves.

3. The shielding system of claim 2 wherein the shielding system is configured to function as a Faraday cage.

4. The shielding system of claim 1 wherein the electroconductive layer is applied to the resealable enclosure.

5. The shielding system of claim 1 wherein the electroconductive layer is constructed, at least in part, from a metallic material.

6. The shielding system of claim 1 wherein the handheld device is a cellular telephone.

7. The shielding system of claim 1 wherein the resealable enclosure includes:
a compartment enclosure portion, and
a lid enclosure portion.

8. The shielding system of claim 7 wherein the electroconductive layer includes an electroconductive compartment layer configured to shield the compartment enclosure portion.

9. The shielding system of claim 7 wherein the electroconductive layer includes an electroconductive lid layer configured to shield the lid enclosure portion.

10. The shielding system of claim 1 wherein the resealable enclosure is configured to function as a case for the handheld device.

11. The shielding system of claim 1 wherein the resealable enclosure is constructed of a rigid material.

12. The shielding system of claim 1 wherein the resealable enclosure is constructed of a non-rigid material.

13. A shielding system comprising:
a resealable enclosure configured to receive the cellular telephone; and
an electroconductive layer configured to magnetically and/or electrically shield the cellular telephone, wherein the electroconductive layer is applied to the resealable enclosure.

14. The shielding system of claim 13 wherein the electroconductive layer is configured to shield the handheld device from radio-frequency waves.

15. The shielding system of claim 13 wherein the electroconductive layer is constructed, at least in part, from a metallic material.

16. The shielding system of claim 13 wherein:
the resealable enclosure includes a compartment enclosure portion and a lid enclosure portion; and
the electroconductive layer includes an electroconductive compartment layer configured to shield the compartment enclosure portion and an electroconductive lid layer configured to shield the lid enclosure portion.

17. A shielding system comprising:
a resealable enclosure configured to receive a cellular telephone, the resealable enclosure including a compartment enclosure portion and a lid enclosure portion; and
an electroconductive layer configured to magnetically and/or electrically shield the cellular telephone, the electroconductive layer including an electroconductive compartment layer configured to shield the compartment enclosure portion and an electroconductive lid layer configured to shield the lid enclosure portion.

18. The shielding system of claim 17 wherein the shielding system is configured to function as a Faraday cage.

19. The shielding system of claim 17 wherein the electroconductive layer is applied to the resealable enclosure.

20. The shielding system of claim 17 wherein the resealable enclosure is configured to function as a case for the handheld device.
